(19) United States
(12) Patent Application Publication
(10) Pub. No.: US 2003/0186523 A1
(43) Pub. Date: Oct. 2, 2003

(54) Method for forming an improved metal silicide portion in a silicon-containing conductive region in an integrated circuit

(76) Inventors: Karsten Wieczorek, Dresden (DE); Volker Kahlert, Dresden (DE); Manfred Horstmann, Dresden (DE)

Correspondence Address: J. Mike Amerson, Williams, Morgan & Amerson, P.C., Suite 250, 7676 Hilmont, Houston, TX, 77040, US

(21) Appl. No.: 10/282,665

(22) Filed: Oct. 29, 2002

(30) Foreign Application Priority Data
Mar. 28, 2002 (DE) 102 14 065.0

(51) Int. Cl. H01L 21/20; H01L 21/3205; H01L 21/4763

(52) U.S. Cl. 438/584; 438/592; 438/649

(57) ABSTRACT

In one aspect of the present invention, a layer stack comprising at least three material layers is provided on a silicon-containing conductive region to form a silicide portion on and in the silicon-containing conductive region, wherein the layer next to the silicon provides the metal atoms for the chemical reaction, and wherein the following layers provide for a sufficient inertness of the chemical reaction. The method may be carried out as an in situ method, thereby significantly improving throughput and deposition tool performance compared to typical prior art processes, in which at least two deposition chambers have to be used.

### BACKGROUND OF THE INVENTION

1. Field of the Invention

Generally, the present invention relates to the field of fabrication of integrated circuits, and more particularly, to semiconductor devices having metal silicide portions in conductive silicon-containing regions to reduce the sheet resistance of these regions.

2. Description of the Related Art

In modern ultra high density integrated circuits, device features are steadily decreasing to enhance device performance and functionality. Shrinking the feature sizes, however, entails certain problems that may partially offset the advantages obtained by the reduced feature sizes. Generally, reducing the feature sizes of, for example, a transistor element, leads to a decreased channel length in the transistor element and, thus, results in a higher drive current capability and enhanced switching speed of the transistor. In decreasing the feature sizes of these transistor elements, however, the increasing electrical resistance of conductive lines and contact regions, i.e., of regions that provide electrical contact to the periphery of the transistor element, becomes a dominant issue, since the cross-sectional area of these lines and regions decreases with the decreasing feature sizes. However, the cross-sectional area, in combination with the characteristics of the material contained in the conductive lines and contact regions, among others, determines the resistance of the respective line or contact region.

The above problems may be exemplified for a typical critical feature size in this respect, also referred to as critical dimension (CD), such as the extension of the channel of a field effect transistor that forms below a gate electrode between a source region and a drain region of the transistor. Reducing this extension of the channel, commonly referred to as channel length, may significantly improve device performance with respect to fall and rise times during switching the transistor element due to the smaller capacitance between the gate electrode and the channel and due to the decreased resistance of the shorter channel. The shrinking of the channel length, however, also entails the reduction in size of any conductive lines, such as the gate electrode of the field effect transistor, which is commonly formed of polysilicon, and the contact regions that allow electrical contact to the drain and the source regions of the transistor, so that, consequently, the available cross-section for charge carrier transportation is reduced. As a result, the conductive lines and contact regions exhibit a higher resistance unless the reduced cross-section is compensated by improving the electrical characteristics of the material forming the lines and contact regions, such as the gate electrode and the drain and the source contact regions.

It is, therefore, of particular importance to improve the characteristics of conductive regions that are substantially comprised of semiconductor material such as silicon. For instance, in modern integrated circuits, the individual semiconductor devices, such as field effect transistors, capacitors and the like, are primarily based on silicon, wherein the individual devices are connected by silicon lines and metal lines. While the resistivity of the metal lines may be improved by replacing the commonly used aluminum by, for example, copper, process engineers are confronted with a challenging task when an improvement of the electrical characteristics of silicon-containing semiconductor lines and semiconductor contact regions is required.

Typically, these silicon-containing regions are treated to receive a metal silicide portion thereon, which exhibits a remarkably smaller sheet resistance than silicon, even in a heavily doped state.

With reference to FIGS. 1a-1c, a typical prior art process flow for forming metal silicide portions on a silicon-containing conductive region will be described. FIG. 1a schematically shows a cross-sectional view of a field effect transistor 100 formed in a substrate 101, which may be a silicon substrate or any other appropriate substrate for carrying the field effect transistor 100. The dimensions of the field effect transistor 100 are defined by a shallow trench isolation 103 that may be formed of an insulating material, such as silicon dioxide. A gate insulation layer 106, comprising, for example, silicon dioxide, separates a gate electrode 109, substantially comprised of polysilicon, from the well region 102, which may contain N-type and/or P-type dopant atoms, depending on the required characteristics of the field effect transistor 100. Moreover, source and drain regions, both indicated by reference sign 105, are provided in the well region 102 and are inversely doped to the well region 102. The surface region of the well region 102 that underlies the gate insulation layer 106 is also referred to as the channel region. The lateral distance in FIG. 1a separating the drain and source regions 105 is referred to as the channel length. Sidewall spacers 107, comprising, for example, silicon dioxide or silicon nitride, are formed in contact with the sidewalls of the gate electrode 109. On top of the drain and source regions 105 and the gate electrode 109, metal silicide portions 108 are formed, which typically comprise a cobalt silicide (CoSi₂) in a low-ohmic state to reduce the resistance of the respective silicon-containing conductive region, such as the gate electrode 109 and the source and drain regions 105.

The structure shown in FIG. 1a is typically formed by the following process steps. First, after forming the trench isolation 103 by etching trenches and refilling with silicon dioxide, the gate insulation layer 106 is formed, for example, by an oxidizing process. Next, a polysilicon layer is deposited and patterned to form the gate electrode 109 by sophisticated photolithography techniques. Thereafter, a first implantation step is performed to define lightly doped regions in the source and drain regions 105 and then the sidewall spacers 107 are formed that act as an implantation mask in a subsequent implantation step for defining the source and drain regions 105. Next, a layer of refractory metal, for example, including titanium, tantalum, zirconium, cobalt, nickel and the like, is deposited over the structure shown in FIG. 1a. Typically, the metal is deposited by sputter deposition in a sputter tool including a corresponding target to provide the required metal.

FIG. 1b schematically shows an enlarged cross-sectional view of a portion of the drain region 105, including the layer of refractory metal 110, deposited on the drain region 105. On top of the layer of refractory metal 110, a cap layer 111 is located and may typically comprise titanium or titanium nitride, when the refractory metal of the layer 110 is substantially formed of cobalt. The cap layer 111 is typically formed by sputter deposition, wherein the substrate 101 is treated in a separate deposition chamber to form the cap layer 111.

Thereafter, a first anneal step at a first average temperature, typically in the range of 440-600° C. for cobalt as the refractory metal, is performed to initiate a chemical reaction between the refractory metal in the layer 110 and the silicon in the drain region 105. It should be noted that a corresponding reaction, of course, also takes place in the gate electrode 109 and the source region 105. During this first annealing step, the metal of the layer 110, for example cobalt, and the silicon in the region 105 are subjected to diffusion and form a cobalt monosilicide. As this reaction takes place, the cap layer 111, if substantially comprising titanium, acts as a so-called gettering layer that preferably reacts with any oxygen atoms prevailing in the anneal ambient to form titanium oxide. Thus, the titanium cap layer 111 will significantly reduce any oxidation of the underlying cobalt in the layer 110, which could otherwise form a cobalt oxide and would increase the resistance of the finally obtained silicide layer. However, upon diffusion during the first anneal step, titanium and cobalt tend to form a compound which does not substantially undergo a reaction with silicon and, thus, does not contribute to a low ohmic silicide portion.

On the other hand, if the cap layer 111 substantially comprises titanium nitride, the cap layer 111 acts as a substantially inert layer during the first annealing step; however, it provides only a moderate capability for protecting the underlying cobalt from being oxidized by residual oxygen in the anneal ambient. Moreover, during the annealing and the formation of the cobalt monosilicide, grain boundaries build up, in which titanium may accumulate when a titanium cap layer 111 is employed.

Subsequently, the cap layer 111 and the non-reacted cobalt of the layer 110 are removed by a selective wet etching process. Next, a second annealing step is carried out at a higher average temperature than in the first annealing step, typically in the range of 650-700° C., if cobalt has been used in the layer 110, to transform the cobalt monosilicide into a more stable cobalt disilicide, which exhibits a remarkably lower sheet resistance than the cobalt monosilicide. As previously noted, in the case of a titanium cap layer 111, the titanium may have accumulated at the grain boundaries of the cobalt monosilicide and, thus, the main diffusion path for the chemical reaction during the second annealing step may significantly be hindered by the accumulated titanium.

Moreover, as shown in FIG. 1c, a cobalt titanium layer 112 may have formed during the initial annealing step and thus a thickness of the silicide portion 108 is reduced. Moreover, due to the accumulated titanium at the grain boundaries, the interface 113 of the finally obtained silicide portion 108 and the underlying silicon-containing region 105 may be relatively rough and, therefore, exhibit an increased electrical resistance owing to increased scattering of charge carriers. If a titanium nitride layer is used as the cap layer 111, the generation of the cobalt titanium layer 112 may substantially be avoided, but instead the finally obtained silicide portion 108 may comprise a considerable amount of cobalt oxide, thereby also increasing the electrical resistance of the silicide portion 108.

As a result, although the prior art processing allows one to significantly improve the overall resistance of silicon-containing conductive regions by forming silicide portions in these regions, there is still room for improvement with respect to quality of the silicided portion and in view of process optimization.

### SUMMARY OF THE INVENTION

Generally, the present invention is directed to a method for forming a silicided portion in a silicon-containing conductive region, wherein a stack of layers is provided, in which one or more metal layers provide the metal for forming the metal silicide portion, while other layers in the stack are provided to protect the underlying metal layer during the initiation of a chemical reaction between the metal and the silicon. Moreover, according to one aspect, the complex deposition technique requiring two separate deposition chambers may be remarkably simplified by providing an in situ method for forming the layer stack, thereby allowing the deposition of the metal layer and of the protective layers in a single deposition chamber.

According to one illustrative embodiment of the present invention, a method of forming regions of reduced resistance in a silicon-containing conductive region comprises the provision of a substrate having formed thereon the silicon-containing conductive region and the deposition of a layer stack on the silicon-containing conductive region, wherein the layer stack comprises a first and a second metal layer and a metal nitrogen compound layer positioned between the first and the second metal layer. Additionally, the method comprises heat treating the substrate to form a metal silicide portion in the silicon-containing conductive region.

In a further illustrative embodiment of the present invention, a method of forming a silicide portion in a silicon-containing conductive region formed on a substrate comprises depositing a metal on the silicon-containing conductive region in a reactive plasma ambient. Moreover, a nitrogen-containing gas is supplied to the reactive plasma ambient for subsequently depositing a metal nitrogen compound. Thereafter, the supply of the nitrogen-containing gas is discontinued to deposit the metal again. Additionally, a heat treatment is carried out to form the metal silicide portion, wherein the metal silicide is formed substantially from metal located between the silicon-containing region and the metal nitrogen compound.

### BRIEF DESCRIPTION OF THE DRAWINGS

The invention may be understood by reference to the following description taken in conjunction with the accompanying drawings, in which like reference numerals identify like elements, and in which:

FIGS. 1a-1c schematically show cross-sectional views of a semiconductor device including a silicided portion formed according to a typical prior art process; and

FIGS. 2a-2d schematically show cross-sectional views of a semiconductor device during various manufacturing stages pursuant to one illustrative embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

In the following, illustrative embodiments of the present invention will be described by referring to a field effect transistor including silicon-containing conductive regions. It should be understood, however, that the present invention is applicable to any silicon-containing conductive region provided in an integrated circuit. For example, certain die areas or individual semiconductor elements may be connected by polysilicon lines, which may, in accordance with design requirements, have a relatively small cross-sectional area so that any improvement in the conductivity of these lines will significantly contribute to an enhancement of the overall performance of the integrated circuit.

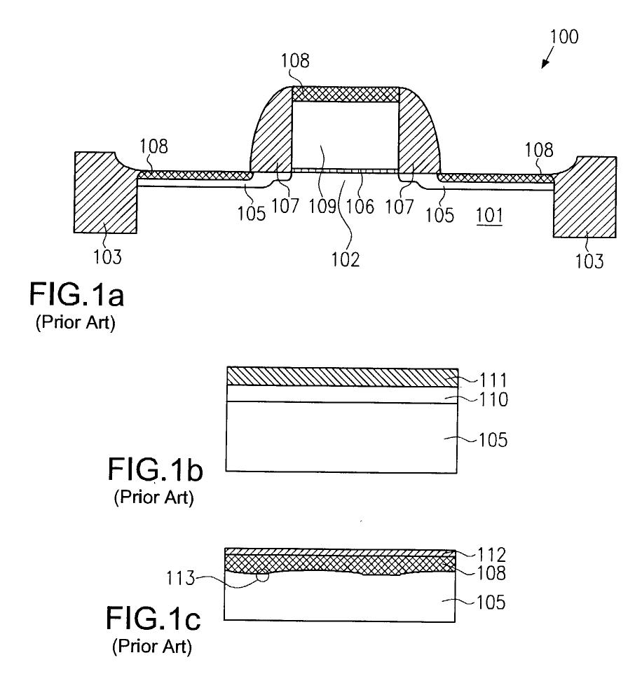

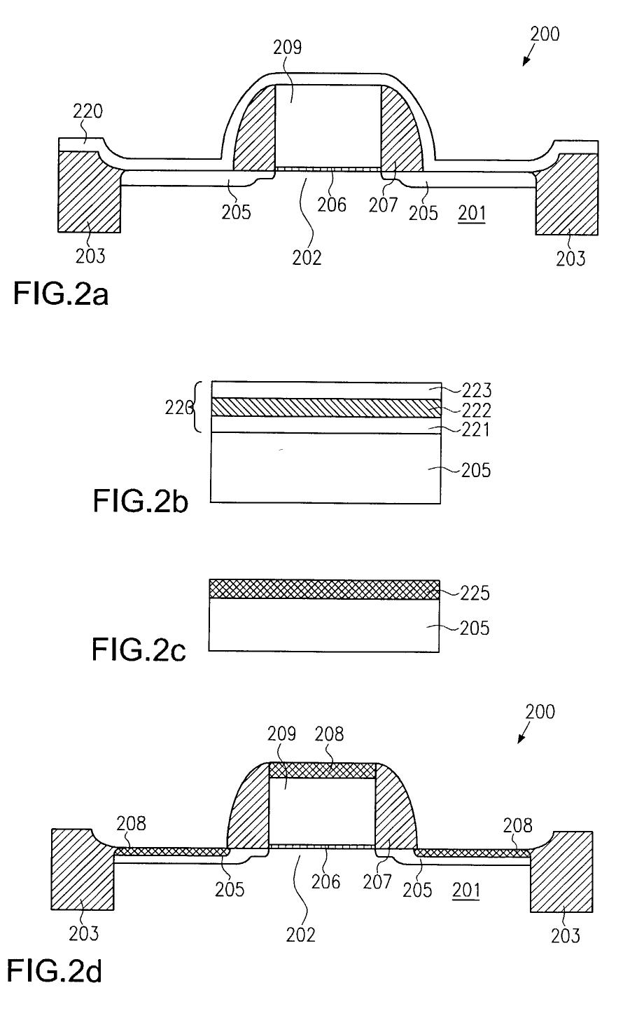

FIG. 2a shows a schematic cross-sectional view of a semiconductor element 200 in the form of a field effect transistor having essentially the same components and parts as already described in FIG. 1a. The corresponding components and parts are indicated by the same reference numerals except for a leading “2” instead of a leading “1.” Thus, the semiconductor element 200 comprises shallow trench isolations 203 formed in a substrate 201, wherein the substrate 201 may be any appropriate substrate including, for example, a silicon substrate, a silicon-on-insulator substrate, and the like. Drain and source regions 205 are separated by a well region 202 having a central portion over which a gate insulation layer 206 is formed that electrically isolates a gate electrode 209 from the well region 202. Moreover, sidewall spacers 207 are located at the sidewalls of the gate electrode 202.

The process flow for forming the semiconductor element 200 may include substantially the same process steps as already described with reference to FIG. 1a. Thus, a corresponding description is omitted. Moreover, the semiconductor element 200 shown, in FIG. 2a comprises a layer stack 220 (as described more fully below) that is provided for the subsequent formation of silicided portions in the drain and the source regions 205 and the gate electrode 209.

FIG. 2b schematically shows an enlarged cross-sectional view of a portion of the semiconductor element 200 including the layer stack 220 and a portion of the underlying silicon-containing region, for example, the region 205. According to one particular embodiment, the layer stack 220 comprises three layers, a first metal layer 221, a second layer 222 comprising a metal nitrogen compound, and a third layer 223 in the form of a metal layer. The first metal layer 221 may comprise a refractory metal or any suitable alloy thereof, including, for example, cobalt, titanium, zirconium, tantalum, tungsten, nickel, and the like. The second layer 222 may comprise a metal nitrogen compound, such as a metal nitride, formed from one of the above-cited refractory metals. The third layer 223 may comprise a metal or an alloy of metals including, for example, any of the above-cited metals. The thickness of the individual layers 221, 222 and 223 is selected to meet the specific requirements. That is, the first layer 221 is the material source for the metal silicide portion to be formed in and on the silicon-containing conductive region 205. Thus, the thickness of the first layer 221 is selected to obtain the required thickness of the silicide portions to be formed. The thickness of the second layer 222, which will serve as an inert layer, that is, as a diffusion barrier layer substantially hindering diffusion from the first layer 221 to the second layer 222 and/or to the third layer 223 and a chemical reaction between the first layer 221 and the second layer 222 in the subsequent process steps for forming the metal silicide portions, is selected so as to ensure a sufficient protection of the underlying first layer 221 in the subsequent anneal step. For example, if the metal nitride in the second layer 222 is titanium nitride, a typical layer thickness is in the range of approximately 10-100 nm. The thickness of the third layer 223, which will serve in the subsequent anneal step as a gettering layer reacting with oxygen atoms or other reactive byproducts to form a metal oxide or any other compound, is accordingly preferably selected to substantially consume all of the oxygen atoms or molecules hitting the surface of the third layer 223. Typically, a thickness in the range of approximately 10-30 nm is sufficient to maintain the degree of undesired oxidation in the first layer 221 within a tolerable range.

In one particular embodiment, the first layer 221 and the third layer 223 comprise substantially the same metal and the second layer 222 substantially comprises a metal nitride formed from the same metal which forms the first and third layers. Using the same metal for the first, the second and the third layers 221, 222 and 223 offers the following advantages.

Preferably, in manufacturing ultra high density integrated circuits on large diameter substrates, metal layers are deposited by physical vapor deposition, such as sputter deposition, due to the relatively high degree of uniformity that is achievable over the entire substrate surface. During sputter deposition, the substrate, such as the substrate 201, is inserted into a reaction chamber (not shown) containing a target, that is, usually a disk-shaped material that is to be deposited on the substrate, and means for generating a plasma ambient. Typically, a plasma is generated using a noble gas, such as argon, to direct ions and electrons to the target material to liberate target atoms. A portion of the liberated atoms then migrates to the substrate and condenses thereon to form a metal layer, such as the first layer 221. The process parameters of the sputter deposition, such as chamber pressure, power supplied to the plasma generating means, any DC or AC bias voltage supplied to the substrate, the distance between the target and the substrate, the duration of the deposition process and the like, may be controlled to adjust the thickness of the first layer 221 in accordance with design requirements. As sputter deposition tools and processes are already well-established in the art, any detailed description thereof will be omitted.

After the first layer 221 has been deposited with the required thickness, a nitrogen-containing gas, for example, nitrogen (N₂), is added to the plasma ambient. It has been found that many refractory metals, such as titanium, zirconium, tantalum, tungsten and the like, form nitrogen compounds during sputter deposition in the presence of nitrogen so that the second layer 222 may be formed as a metal nitride layer. Again, the deposition process parameters, including the parameters pointed out above, and particularly the flow rate of nitrogen supplied to the reactive plasma ambient, may be controlled to adjust the thickness and the characteristics of the second layer 222. After a desired thickness is obtained, the nitrogen supply is discontinued, wherein the plasma ambient is still maintained so that increasingly more metal than metal nitride is deposited on the substrate. This process progresses until substantially all of the residual nitrogen gas is consumed so that finally a substantially “pure” metal layer 223 is produced.

Furthermore, any nitrogen captured in the target material, or any metal nitride deposited on the target and on the chamber walls may be removed during the deposition process without nitrogen supply so that the contamination with metal nitride in a subsequent sputter deposition process is minimized. The deposition process for the third layer 223 is stopped when a required thickness is achieved, or when a required degree of “cleanliness” in the deposition chamber is established. Since the third layer 223 will only act as a sacrificial layer, the thickness is not critical as long as a minimum required effectiveness in gettering oxygen atoms is guaranteed. Consequently, according to this particular embodiment, a layer stack 220 including the three layers 221, 222 and 223 may be formed in an in situ sputter deposition process, thereby significantly improving throughput and tool performance.

According to a further illustrative embodiment, the first layer 221 may be deposited in a first plasma ambient to form, for example, a cobalt layer 221, and subsequently the substrate 201 is exposed to a second plasma ambient including a second target material, for example, titanium, and a nitrogen-containing gas component. After deposition of a titanium nitride layer, the supply of the nitrogen-containing gas is discontinued and, as described with reference to the foregoing embodiment, gradually a titanium layer 223 is deposited while at the same time the sputter target is decontaminated, as is explained above. In this way, a material composition may be selected wherein the first layer 221 is chosen to yield an optimized silicide portion, and wherein the second and third layers 222 and 223 are selected to provide for an optimum protection of the first layer 221 during the subsequent heat treatment.

As a next process step, a heat treatment is carried out to initiate a chemical reaction between the silicon in the silicon-containing conductive region 205 and the first metal layer 221. To this end, depending on the type of metal contained in the first layer 221, according to one embodiment, a first anneal step at a first averaged temperature may be performed so as to initiate the chemical reaction between the metal in the first layer 221 and the underlying silicon and to form a metal silicon compound. During this anneal step, the second layer 222 substantially avoids any up and down diffusion of material of the first and third layers 221, 223, which is particularly advantageous when the first and the third layers each comprise a different metal. Furthermore, the second layer 222 does substantially not react with the metal of the first layer 221. Moreover, any reactive element, especially oxygen that may be present in the ambient, is substantially consumed by the third layer 223 by forming a compound, such as an oxide, with these reactive elements.

Thereafter, the second and third layers 222 and 223 are selectively removed and also any excess material of the first layer 221 that has not reacted with the underlying silicon is removed. Such removal may be accomplished by performing a variety of known wet etching processes.

FIG. 2c schematically shows the metal silicon compound 225 formed in and on the silicon-containing conductive region 205 after removal of any excess material. Subsequently, a further heat treatment, such as a second anneal step, at a higher average temperature than in the first heat treatment, is carried out to transform the metal silicon compound into a metal silicide that exhibits a significantly lower resistance than the silicon in the region 205 or the metal silicon compound 225.

FIG. 2d schematically shows the semiconductor element 200 after completion of the second heat treatment, wherein metal silicide portions 208 are formed in and on the source and drain regions 205 and the gate electrode 209. Due to the provision of the second layer 222 during the first heat treatment, the interface between the silicon and the metal silicide region 208 is significantly improved, even if the metal of the first layer 221 differs from that of the third layer 223, since any diffusion activity between these two layers is substantially avoided.

Although the illustrative embodiments described so far refer to a layer stack 220 having three different layers, the layer stack 220 may comprise any appropriate number of layers to achieve the required diffusion barrier function and the required gettering function. In particular, the transition between the second layer 222 and the third layer 223 may be a gradual transition in which the ratio of metal and metal nitride may gradually vary so that the top of the layer stack 220 exhibits an enhanced gettering efficiency, whereas the portion on top of the first metal layer 221 exhibits the required diffusion blocking characteristics. This holds especially true for embodiments using an in situ deposition process, wherein the supply of nitrogen gas may be controlled to obtain the required metal nitride and metal configuration in the second and third layers. Moreover, in one embodiment, the first layer 221 and the second layer 222 may be deposited in an in situ process to form a metal layer 221 and a corresponding nitride layer 222, whereas the third layer 223 may be formed of a different material in a separate deposition process.

It is to be noted that in other embodiments more than three layers may be used in the layer stack 220 to obtain a required protective cap for the silicide forming metal. In other embodiments, especially when an in situ deposition for two or three of the layers is used, the term layer is to describe a layer that is defined essentially by its function rather by its boundary to an overlying or underlying layer. For example, a metal nitride layer that is deposited by sputter deposition with supply of nitrogen and a layer formed, after a certain thickness of metal nitride is obtained, by discontinuing the nitrogen supply may be understood as at least two layers due to the gettering function of the finally formed layer and the inert effect of the former layer, although a clear physical boundary therebetween is difficult to define.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a region of reduced resistance in a silicon-containing conductive region, the method comprising:
providing a substrate having formed thereon said silicon-containing conductive region;
depositing a layer stack on the silicon-containing conductive region, the layer stack comprising a first metal layer, a second metal layer and a metal nitrogen compound layer positioned between said first and second metal layers; and
heat treating the substrate to form a metal silicide portion in said silicon-containing conductive region.

2. The method of claim 1, wherein the first, the second and the metal nitrogen compound layer comprise the same metal.

3. The method of claim 1, wherein depositing said layer stack is carried out in situ.

4. The method of claim 1, wherein depositing said layer stack includes:
Sputter depositing the first metal layer in a plasma ambient;
supplying a nitrogen-containing gas to the plasma ambient to deposit said metal nitrogen compound layer; and
discontinuing the supply of the nitrogen-containing gas to deposit the second metal layer.

5. The method of claim 1, wherein depositing said layer stack includes:
exposing the substrate to a first plasma ambient to deposit the first metal layer;
exposing the substrate to a second plasma ambient, while supplying nitrogen-containing gas to the second plasma ambient to deposit the metal nitrogen compound layer; and
discontinuing the supply of the nitrogen-containing gas to the second plasma ambient to deposit the second metal layer.

6. The method of claim 1, wherein depositing said layer stack includes:
exposing the substrate to a first plasma ambient to deposit the first metal layer;
supplying nitrogen-containing gas to the first plasma ambient to deposit the metal nitrogen compound layer; and
exposing the substrate to a second plasma ambient to deposit the second metal layer.

7. The method of claim 1, wherein heat treating the substrate comprises a first annealing process at a first average temperature and a second annealing process at a second average temperature that is higher than the first average temperature.

8. The method of claim 7, further comprising removing the second metal layer, the metal nitrogen compound layer and non-reacted metal of the first metal layer prior to the second annealing process.

9. The method of claim 1, wherein the first metal layer comprises at least one of cobalt, titanium, zirconium, tantalum, nickel and tungsten.

10. The method of claim 1, wherein the second metal layer comprises at least one of cobalt, titanium, zirconium, tantalum, nickel and tungsten.

11. The method of claim 1, wherein the metal nitrogen compound layer comprises at least one of titanium, tantalum, zirconium, tungsten and nickel.

12. The method of claim 1, wherein said silicon-containing conductive region is a portion of at least one of a gate electrode, a drain region, a source region and a polysilicon line.

13. A method of forming a silicide portion in a silicon-containing conductive region formed on a substrate, the method comprising:
depositing a metal on said silicon-containing conductive region in a plasma ambient;
supplying a nitrogen-containing gas to said plasma ambient to deposit a metal nitrogen compound on said deposited metal;
discontinuing the supply of said nitrogen-containing gas to deposit said metal on said metal nitrogen compound; and
heat treating the substrate to form the metal silicide portion, wherein the metal silicide is formed substantially from the metal located between the silicon-containing conductive region and the metal nitrogen compound.

14. The method of claim 13, wherein the heat treating comprises a first heat treatment for initiating a chemical reaction between the silicon and the metal, whereby the metal deposited after depositing the metal nitrogen compound reacts with reactive components existing in an ambient during said first heat treatment.

15. The method of claim 14, further comprising selectively removing the metal nitrogen compound and metal having not reacted with the silicon.

16. The method of claim 15, further comprising a second heat treatment to convert the silicon metal compound created in the first heat treatment into a low ohmic metal silicide.

17. The method of claim 13, wherein depositing a metal on said silicon-containing conductive region yields a first layer, depositing said metal nitrogen compound yields a second layer acting as an inert layer and depositing said metal on the metal nitrogen compound yields a third layer acting as a gettering layer.

18. The method of claim 17, wherein the first, the second and the third layers are formed by physical vapor deposition.

19. The method of claim 17, wherein the first, the second and the third layers are formed by sputter deposition.

20. The method of claim 13, wherein said metal comprises at least one of titanium, tantalum, zirconium, tungsten and nickel.

21. The method of claim 17, wherein a thickness of the first, second and third layers is adjusted by controlling at least one of the deposition parameters.

22. The method of claim 13, wherein a ratio of the concentration of metal and nitrogen is controlled by controlling at least one of controlling the process of discontinuing the supply of said nitrogen-containing gas and parameters of the plasma ambient.

23. The method of claim 13, wherein said silicon-containing conductive region is a portion of at least one of a gate electrode, a drain region, a source region and a polysilicon line.

24. The method of claim 17, wherein a thickness of the second layer is approximately in the range of 10-100 nanometers.

25. The method of claim 17, wherein a thickness of the third layer is at least 10 nanometers.

26. The method of claim 17, wherein a process duration after discontinuing the supply of said nitrogen-containing gas is controlled to decontaminate said reactive plasma ambient to a predefined degree.
